(19) United States
(12) Patent Application Publication
(10) Pub. No.: US 2026/0074938 A1
(43) Pub. Date: Mar. 12, 2026

(54) SYSTEMS ENCODING DATA ON MULTIPLE CARRIER FREQUENCIES IN A SIGMA DELTA BIT STREAM

(71) Applicant: SiliconIntervention Inc., Kelowna (CA)

(72) Inventor: A. Martin Mallinson, Kelowna (CA)

(73) Assignee: SiliconIntervention Inc., Kelowna (CA)

(21) Appl. No.: 19/327,670

(22) Filed: Sep. 12, 2025

Related U.S. Application Data
(60) Provisional application No. 63/694,068, filed on Sep. 12, 2024.
(60) Provisional application No. 63/694,064, filed on Sep. 12, 2024.

(51) Int. Cl. H04L 27/26; H03K 17/687

(52) U.S. Cl. CPC H04L 27/2627; H03K 17/6871

(57) ABSTRACT

An example system for encoding OFDM data may comprise a processor and a transmitter. The processor may be configured to encode OFDM symbols into a first sigma-delta (ΣΔ) modulated bitstream, such that spectral content of the first sigma-delta (ΣΔ) modulated bitstream contains tones at subcarrier frequencies corresponding to the encoded symbols. The transmitter may be configured to transmit the sigma-delta (ΣΔ) modulated bitstream to a receiver.

### CROSS-REFERENCE TO RELATED APPLICATIONS

This application claims priority to U.S. Provisional Patent Application No. 63/694,068, filed on Sep. 12, 2024, and entitled “Encoding Data on Multiple Carrier Frequencies in a Sigma Delta Bit Stream” and U.S. Provisional Patent Application No. 63/694,064, filed on Sep. 12, 2024, and entitled “Analog Neural Network Calculating FFT Using Current”, which are both incorporated in entirety herein by reference.

### FIELD OF THE INVENTION

Embodiments of the present inventions are generally related to analog circuitry and, more particularly, analog circuitry for frequency decomposition in a sigma delta bit stream.

### BACKGROUND

Neural networks, run on devices such as IoT or “edge” devices, often require analog to digital converters (ADCs). Digital neural networks used in these IoT and edge applications that need an ADC prepare the data by using a typically external ADC to convert into the digital input to the neural network. Thus, although the network may be digital, it requires analog components (the ADC) to enable its operation.

Orthogonal Frequency Division Multiplexing (OFDM) is well known in the art. OFDM is a modulation technique that is used in several applications ranging from cellular systems (3G/4G/5G, WiMAX), wireless local area networks (LANs), digital audio radio, underwater communications, and even optical light modulation. OFDM use in communications has come to depend upon Forward Error Correction (FEC) and sophisticated interleaving to reduce dropout losses

An analog neural network may accommodate the ADC function as part of its construction, and to function as a neural network must adequately manage weighted addition and the connectivity to the next layer of the network. In one example of an analog neural network, the neuron must accurately perform the weighted addition. FIG. 1 is a schematic of a neural network calculating a Fast Fourier transform in the prior art. For example, consider Out=W1*A+W2*B . . . where A and B (etc.) are the inputs and Wn are the weights. This is a convolution operation and is the reason why this class of NN is called a Convolutional NN or “CNN.”

### SUMMARY

An example system for encoding OFDM data may comprise a processor and a transmitter. The processor may be configured to encode OFDM symbols into a first sigma-delta (ΣΔ) modulated bitstream, such that spectral content of the first sigma-delta (ΣΔ) modulated bitstream contains tones at subcarrier frequencies corresponding to the encoded symbols. The transmitter may be configured to transmit the first sigma-delta (ΣΔ) modulated bitstream to a receiver. In some embodiments, the transmitter is configured to apply a filter to the first sigma-delta (ΣΔ) modulated bitstream to remove frequency content above a fraction of a sigma delta clock rate (e.g., above the highest frequency OFDM tone) to create a filtered sigma-delta (ΣΔ) modulated bitstream and transmit the filtered sigma-delta (ΣΔ) modulated bitstream at a reduced data rate to the receiver.

In some embodiments, the sigma-delta (ΣΔ) modulated bitstream is a one-bit sigma-delta (ΣΔ) modulated bitstream. The receiver that receives the sigma-delta (ΣΔ) modulated bitstream from the transmitter, may accumulate samples of the sigma-delta (ΣΔ) modulated bitstream, apply an FFT to recover the OFDM symbols, and decode the OFDM symbols.

In various embodiments, the filter is a cascaded integrator-comb (CIC) filter. For example, the CIC filter is a 6-bit CIC filter configured to output a predetermined number of bits and transmit the sigma-delta (ΣΔ) modulated bitstream to the receiver, the reduced data rate being at a rate, for example, of 1/64th of a clock. In some embodiments, data to be encoded into the OFDM symbols is received from a multichannel device generating complex signals to be encoded on more than one channel. In some embodiments, the reduced data rate is less than a Pulse Code Modulation (PCM) serial clock.

In various embodiments, the processor inserts a tone at a point where noise begins to fall at a percentage of clock rate with respect to increasing an over sampling ratio (OSR). For example, the processor may insert the tone at approximately 40% of a sigma-delta (ΣΔ) clock rate. In some embodiments, there are a plurality of carriers and the tones are at points such that a data rate of a data transfer is a multiple of the sigma-delta (ΣΔ) clock rate.

In some embodiments, the system uses a first analog circuit to assist in encoding the data. The first analog system may comprise a first transistor M1 including a first source configured to receive a first current, a first drain coupled to a third drain at a third transistor M3, and a signal input applied to a first gate, a voltage at the first gate determining how much current flows through the first transistor M1. The first analog circuit may include a second transistor M2, including a second source configured to receive the first current, a second drain coupled to a fourth drain at fourth transistor M4, and the signal input applied to a second gate, the voltage at the second gate determining how much current flows through the second transistor M2. The first analog circuit may include the third transistor M3, including a third source configured to receive a second current and the signal input applied to a third gate, the voltage at the third gate determining how much current flows through the third transistor M3. Further, the first analog circuit may include the fourth transistor M4, including a fourth source configured to receive the second current and the signal input applied to a first gate, the voltage at the first gate determining how much current flows through the fourth transistor M4.

In some embodiments, the first transistor M1 and the fourth transistor M4 form a differential pair. In some embodiments, the second transistor M2 and the third transistor M3 are active loads that improve gain. In various embodiments, the second transistor M2 and the third transistor M3 operate in parallel with M1 and M4 respectively and so split the current of the initial pair M1 and M4 into two parts. M2 directs a part of the M1 current into the drain of M4, and M3 directs part of the M4 current into the drain of M1. The current into the sources of the group of devices M1-M4 results in currents out of the drains of the group that are dependent on the relative sizes of the devices. The factor by which the output current difference in the drains, differs from input current difference at the sources, is adjustable by using different sizes, or equivalently different numbers of individual devices, in construction of M1-M4. It will be appreciated that this functional arrangement of transistors may be repeated throughout one or more circuits (e.g., See FIGS. 5 and 6 showing similar repeated arrangements of transistors with the same internal functionality). The first, second, third, and fourth transistors may be any kind of FETs or other transistors (e.g., NMOS FETs in the example of FIG. 6).

The upper rotator X1 may further include a fifth transistor M5, including a fifth source configured to receive the first current, a fifth drain coupled to a seventh drain at a seventh transistor M7, and a signal input applied to a fifth gate, the voltage at the fifth gate determining how much current flows through the fifth transistor M5. The upper rotator may include a sixth transistor M6, including a sixth source configured to receive the first current, a sixth drain coupled to an eighth drain at fourth transistor M4, and the signal input applied to a sixth gate, the voltage at the sixth gate determining how much current flows through the sixth transistor M6. Further, the upper rotator X1 may include the seventh transistor M7, including a seventh source configured to receive the second current and the signal input applied to a seventh gate, the voltage at the seventh gate determining how much current flows through the seventh transistor M7. Moreover, the upper rotator X1 may include the eighth transistor M8, including an eighth source configured to receive the second current and the signal input applied to an eighth gate, the voltage at the eighth gate determining how much current flows through the eighth transistor M8. M5 through M8 may operate in a similar manner to M1 through M4 as described above (e.g., they may be arranged in the same functional arrangement discussed herein). The factor by which the output currents of M5-M8 differ from the inputs is generally different from the factor created by M1-M4.

In some embodiments, the first, second, third, and fourth transistors of the first analog circuit (e.g., upper rotator X1) apply to a real part of a complex number, and the fifth, sixth, seventh, and eighth transistors apply to an imaginary part of the complex number. For example, the first current is the real part of the signal, and the second current is the imaginary part of the signal. In various embodiments, a first area of the first, second, third, and fourth transistors of the first analog circuit is such that the first signal is multiplied by a cosine of 60, and a second area of the fifth, sixth, and seventh transistors is such that the first signal is multiplied by a sine of 60.

The first analog circuit may further comprise a ninth, tenth, eleventh, twelfth, thirteenth, fourteenth, fifteenth, and sixteenth transistor. The ninth transistor M9 may include a ninth source configured to receive a third current, a ninth drain coupled to an eleventh drain at an eleventh transistor M11, and the signal input applied to a ninth gate, the voltage at the ninth gate determining how much current flows through the ninth transistor M9. The tenth transistor M10 may include a tenth source configured to receive the third current, a tenth drain coupled to a twelfth drain at twelfth transistor M12, and the signal input applied to a tenth gate, the voltage at the tenth gate determining how much current flows through the tenth transistor M10. The eleventh transistor M11 may include an eleventh source configured to receive a fourth current, the signal input applied to an eleventh gate, and the voltage at the eleventh gate, which determines how much current flows through the eleventh transistor M11. The twelfth transistor M12 may include a twelfth source configured to receive the fourth current and the signal input applied to a twelfth gate, the voltage at the twelfth gate determining how much current flows through the twelfth transistor M12. The thirteenth transistor M13 may include a thirteenth source configured to receive the third current, a thirteenth drain coupled to a fifteenth drain at a fifteenth transistor M15, and the signal input applied to a thirteenth gate, the voltage at the thirteenth gate determining how much current flows through the thirteenth transistor M13. The fourteenth transistor M14 may include a fourteenth source configured to receive the third current, a fourteenth drain coupled to a sixteenth drain at a sixteenth transistor M16, and the signal input applied to a fourteenth gate, the voltage at the fourteenth gate determining how much current flows through the fourteenth transistor M14. The fifteenth transistor M15 may include a fifteenth source configured to receive the fourth current and the signal input applied to a fifteenth gate, the voltage at the fifteenth gate determining how much current flows through the fifteenth transistor M15. The sixteenth transistor M16 may include a sixteenth source configured to receive the fourth current and the signal input applied to a sixteenth gate, the voltage at the sixteenth gate determining how much current flows through the sixteenth transistor M16.

A third area of the ninth, tenth, eleventh, and twelfth transistors M9, M10, M11, and M12 may be such that the third signal is multiplied by a cosine of 60 and a fourth area of the thirteenth, fourteenth, fifteenth, and sixteenth transistors M13, M14, M15, and M16 may be such such that the first signal is multiplied by a sine of 60.

The second analog circuit (X2 middle rotator) may include a first, second, third, fourth, fifth, sixth, seventh, eighth, ninth, tenth, eleventh, twelfth, thirteenth, fourteenth, fifteenth, and sixteenth transistor. The first transistor M1 may include a first source configured to receive a fifth current, a first drain coupled to a third drain at a third transistor M3, and a signal input applied to a first gate, a voltage at the first gate determining how much current flows through the first transistor M1. The second transistor M2 may include a second source configured to receive the fifth current, a second drain coupled to a fourth drain at fourth transistor M4, and the signal input applied to a second gate, the voltage at the second gate determining how much current flows through the second transistor M2. The third transistor M3 may include a third source configured to receive a sixth current, the signal input applied to a third gate, and the voltage at the third gate, which determines how much current flows through the third transistor M3. The fourth transistor M4 may include a fourth source configured to receive the sixth current and the signal input applied to a first gate, the voltage at the first gate determining how much current flows through the fourth transistor M4. The fifth transistor M5 may include a fifth source configured to receive the fifth current, a fifth drain coupled to a seventh drain at a seventh transistor M7, and a signal input applied to a fifth gate, the voltage at the fifth gate determining how much current flows through the fifth transistor M5. The sixth transistor M6 may include a sixth source configured to receive the fifth current, a sixth drain coupled to an eighth drain at fourth transistor M4, and the signal input applied to a sixth gate, the voltage at the sixth gate determining how much current flows through the sixth transistor M6. The seventh transistor M7 may include a seventh source configured to receive the sixth current and the signal input applied to a seventh gate, the voltage at the seventh gate determining how much current flows through the seventh transistor M7. The eighth transistor M8 may include an eighth source configured to receive the sixth current and the signal input applied to an eighth gate, the voltage at the eighth gate determining how much current flows through the eighth transistor M8. The ninth transistor M9 may include a ninth source configured to receive a seventh current, a ninth drain coupled to an eleventh drain at an eleventh transistor M11, and the signal input applied to a ninth gate, the voltage at the ninth gate determining how much current flows through the ninth transistor M9. The tenth transistor M10 may include a tenth source configured to receive the seventh current, a tenth drain coupled to a twelfth drain at twelfth transistor M12, and the signal input applied to a tenth gate, the voltage at the tenth gate determining how much current flows through the tenth transistor M10. The eleventh transistor M11 may include an eleventh source configured to receive an eighth current, the signal input applied to an eleventh gate, and the voltage at the eleventh gate, which determines how much current flows through the eleventh transistor M11. The twelfth transistor M12 may include a twelfth source configured to receive the eighth current and the signal input applied to a twelfth gate, the voltage at the twelfth gate determining how much current flows through the twelfth transistor M12. The thirteenth transistor M13 may include a thirteenth source configured to receive the seventh current, a thirteenth drain coupled to a fifteenth drain at a fifteenth transistor M15, and the signal input applied to a thirteenth gate, the voltage at the thirteenth gate determining how much current flows through the thirteenth transistor M13. The fourteenth transistor M14 may include a fourteenth source configured to receive the seventh current, a fourteenth drain coupled to a sixteenth drain at a sixteenth transistor M16, and the signal input applied to a fourteenth gate, the voltage at the fourteenth gate determining how much current flows through the fourteenth transistor M14. The fifteenth transistor M15 may include a fifteenth source configured to receive the eighth current and the signal input applied to a fifteenth gate, the voltage at the fifteenth gate determining how much current flows through the fifteenth transistor M15. The sixteenth transistor M16 may include a sixteenth source configured to receive the eighth current and the signal input applied to a sixteenth gate, the voltage at the sixteenth gate determining how much current flows through the sixteenth transistor M16. In some embodiments, the source of the first transistor of the first analog circuit is coupled to the drain of the first and third transistors of the second analog circuit, the source of the fourth transistor of the first analog circuit is coupled to the drain of the second and fourth transistors of the second analog circuit, the source of the ninth transistor of the first analog circuit is coupled to the drain of the ninth and eleventh transistors of the second analog circuit, and the source of the twelfth transistor of the first analog circuit is coupled to the drain of the tenth and twelfth transistors of the second analog circuit.

In some embodiments, a fifth area of the first, second, third, and fourth transistors of the second analog circuit are such that the first signal is multiplied by a cosine of 60, a sixth area of the fifth, sixth, seventh, and eighth transistors, are such that the first signal is multiplied by a sine of 60, a seventh area of the ninth, tenth, eleventh, and twelfth transistors of the second analog circuit are such that the first signal is multiplied by a cosine of 60, an eighth area of the thirteenth, fourteenth, fifteenth, and sixteenth transistors of the second analog circuit are such that the first signal is multiplied by a sine of 60.

The third analog circuit (X3 lower rotator) may include a first, second, third, fourth, fifth, sixth, seventh, eighth, ninth, tenth, eleventh, twelfth, thirteenth, fourteenth, fifteenth, and sixteenth transistor. The first transistor M1 may include a first source configured to receive a fifth current, a first drain coupled to a third drain at a third transistor M3, and a signal input applied to a first gate, a voltage at the first gate determining how much current flows through the first transistor M1. The second transistor M2 may include a second source configured to receive the fifth current, a second drain coupled to a fourth drain at fourth transistor M4, and the signal input applied to a second gate, the voltage at the second gate determining how much current flows through the second transistor M2. The third transistor M3 may include a third source configured to receive a sixth current, the signal input applied to a third gate, and the voltage at the third gate, which determines how much current flows through the third transistor M3. The fourth transistor M4 may include a fourth source configured to receive the sixth current and the signal input applied to a first gate, the voltage at the first gate determining how much current flows through the fourth transistor M4. The fifth transistor M5 may include a fifth source configured to receive the fifth current, a fifth drain coupled to a seventh drain at a seventh transistor M7, and a signal input applied to a fifth gate, the voltage at the fifth gate determining how much current flows through the fifth transistor M5. The sixth transistor M6 may include a sixth source configured to receive the fifth current, a sixth drain coupled to an eighth drain at fourth transistor M4, and the signal input applied to a sixth gate, the voltage at the sixth gate determining how much current flows through the sixth transistor M6. The seventh transistor M7 may include a seventh source configured to receive the sixth current and the signal input applied to a seventh gate, the voltage at the seventh gate determining how much current flows through the seventh transistor M7. The eighth transistor M8 may include an eighth source configured to receive the sixth current and the signal input applied to an eighth gate, the voltage at the eighth gate determining how much current flows through the eighth transistor M8. The ninth transistor M9 may include a ninth source configured to receive a seventh current, a ninth drain coupled to an eleventh drain at an eleventh transistor M11, and the signal input applied to a ninth gate, the voltage at the ninth gate determining how much current flows through the ninth transistor M9. The tenth transistor M10 may include a tenth source configured to receive the seventh current, a tenth drain coupled to a twelfth drain at twelfth transistor M12, and the signal input applied to a tenth gate, the voltage at the tenth gate determining how much current flows through the tenth transistor M10. The eleventh transistor M11 may include an eleventh source configured to receive an eighth current, the signal input applied to an eleventh gate, and the voltage at the eleventh gate, which determines how much current flows through the eleventh transistor M11. The twelfth transistor M12 may include a twelfth source configured to receive the eighth current and the signal input applied to a twelfth gate, the voltage at the twelfth gate determining how much current flows through the twelfth transistor M12. The thirteenth transistor M13 may include a thirteenth source configured to receive the seventh current, a thirteenth drain coupled to a fifteenth drain at a fifteenth transistor M15, and the signal input applied to a thirteenth gate, the voltage at the thirteenth gate determining how much current flows through the thirteenth transistor M13. The fourteenth transistor M14 may include a fourteenth source configured to receive the seventh current, a fourteenth drain coupled to a sixteenth drain at a sixteenth transistor M16, and the signal input applied to a fourteenth gate, the voltage at the fourteenth gate determining how much current flows through the fourteenth transistor M14. The fifteenth transistor M15 may include a fifteenth source configured to receive the eighth current and the signal input applied to a fifteenth gate, the voltage at the fifteenth gate determining how much current flows through the fifteenth transistor M15. The sixteenth transistor M16 may include a sixteenth source configured to receive the eighth current and the signal input applied to a sixteenth gate, the voltage at the sixteenth gate determining how much current flows through the sixteenth transistor M16. In some embodiments, the source of the first transistor of the second analog circuit is coupled to the drain of the first and third transistors of the third analog circuit, the source of the fourth transistor of the second analog circuit is coupled to the drain of the second and fourth transistors of the third analog circuit, the source of the ninth transistor of the second analog circuit is coupled to the drain of the ninth and eleventh transistors of the third analog circuit, and the source of the twelfth transistor of the second analog circuit is coupled to the drain of the tenth and twelfth transistors of the third analog circuit.

In some embodiments, a fifth area of the first, second, third, and fourth transistors of the third analog circuit are such that the first signal is multiplied by a cosine of 60, a sixth area of the fifth, sixth, seventh, and eighth transistors of the third analog circuit are such that the first signal is multiplied by a sine of 60, a seventh area of the ninth, tenth, eleventh, and twelfth transistors of the third analog circuit are such that the first signal is multiplied by a cosine of 60, an eighth area of the thirteenth, fourteenth, fifteenth, and sixteenth transistors of the third analog circuit are such that the first signal is multiplied by a sine of 60.

An example method may comprise a method, comprising: encoding OFDM symbols, by a processor, into a first sigma-delta (ΣΔ) modulated bitstream, such that spectral content of the first sigma-delta (ΣΔ) modulated bitstream contains tones at subcarrier frequencies corresponding to the encoded symbols and transmitting, by a transmitter, the sigma-delta (ΣΔ) modulated bitstream to a receiver.

In some embodiments, the method may further comprise filtering by the transmitter the first sigma-delta (ΣΔ) modulated bitstream to remove frequency content above a fraction of a sigma delta clock rate (e.g., above the highest frequency OFDM tone) to create a filtered sigma-delta (ΣΔ) modulated bitstream transmitting the filtered sigma-delta (ΣΔ) modulated bitstream at a reduced data rate to the receiver.

In some embodiments, the sigma-delta (ΣΔ) modulated bitstream is a one-bit sigma-delta (ΣΔ) modulated bitstream. In some embodiments, the method further comprises receiving, by a receiver the sigma-delta (ΣΔ) modulated bitstream from the transmitter, accumulating samples of the sigma-delta (ΣΔ) modulated bitstream, applying an FFT to recover the OFDM symbols, and decoding the OFDM symbols.

In various embodiments, the filter is a cascaded integrator-comb (CIC) filter. For example, in some embodiments, the method comprises filtering the first sigma-delta (ΣΔ) modulated bitstream by a CIC filter is a 6-bit CIC to remove frequency content above the frequency OFDM band and the reduced rate may be, for example, 1/64th of a clock. In some embodiments, data to be encoded into the OFDM symbols is received from a multichannel device generating complex signals to be encoded on more than one channel. In some embodiments, the reduced data rate is less than a Pulse Code Modulation (PCM) serial clock.

In various embodiments, the method comprises inserting a tone, by the processor, at a point where noise begins to fall at a percentage of clock rate with respect to increasing an over sampling ratio (OSR). For example, the method may comprise inserting the tone, by the processor, at approximately 40% of a sigma-delta (ΣΔ) clock rate. In some embodiments, there are a plurality of carriers and the tones are at points such that a data rate of a data transfer is a multiple of the sigma-delta (ΣΔ) clock rate.

### BRIEF DESCRIPTION OF THE DRAWINGS

FIG. 1 is a schematic of a neural network calculating a Fast Fourier transform in the prior art.

FIG. 2 is a butterfly circuit in the prior art.

FIG. 3 depicts two sets of differential currents that encode real and imaginary parts of a complex number in some embodiments.

FIG. 4 depicts differential currents being split and multiplied by differing factors in some embodiments.

FIG. 5 is an example of complex number rotation in some embodiments.

FIG. 6 depicts stacking calculations without need for additional currents in some embodiments.

FIG. 7 is an example of an alternative butterfly circuit in some embodiments.

FIG. 8 depicts a rotator represented as a FET-like symbol with multiple drains and sources in some embodiments.

FIG. 9 depicts four rotator circuits configured to make a current mode butterfly in some embodiments.

FIG. 10 depicts noise of a single bit high order sigma delta (ΣΔ) vs OSR.

FIG. 11 depicts channel capacity as a fraction of the ΣΔ clock vs. OSR of the single OFDM tone in some embodiments.

FIG. 12 depicts multiple ODFM carriers in the ΣΔ output in some embodiments.

FIG. 13 depicts the decoding of the stream of ΣΔ data having OFDM encoding by a receiving device in some embodiments.

FIG. 14 depicts an example of the implementation of a filter (e.g., a 6-bit Cascaded Integrator-Comb (CIC)) prior to transmission in some embodiments.

FIG. 15 depicts a block diagram of an example digital device according to some embodiments.

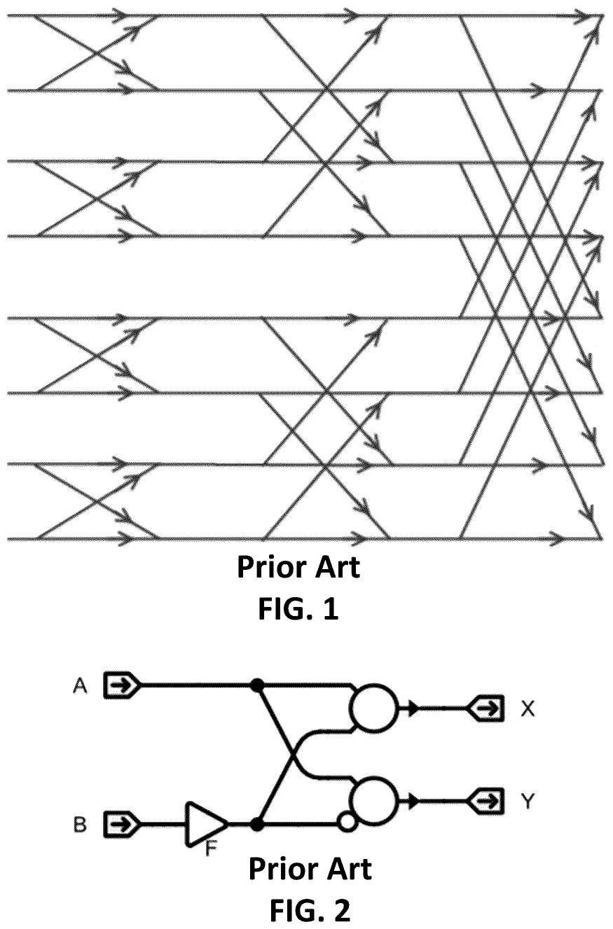

### DETAILED DESCRIPTION

Any property of an electronic system (e.g., voltage, charge, time, and current) is a candidate for a signal representation. For example, an audio system may use the difference of two voltages to represent the sound pressure level, amplifying and reproducing sound.

In some embodiments, analog circuits are constructed as neural networks (NN). The use of neural networks implies the existence of a neuron, an element within the analog neural network that produces a weighted sum of its inputs to present to the next layer of the network. The neuron may or may not have an activation threshold and may or may not be run-time programmable in its weights (as opposed to having fixed weights at chip construction time).

In some embodiments, current differences may be used to encode complex numbers used by a neural network that calculates a signal's fast Fourier transform (FFT). In various embodiments, differing areas of arrays of FET devices may encode weights, currents may be transmitted in the complex interconnect to the next layer, and succeeding layers may reuse the same current consumed by the first layer. In some embodiments, the voltage headroom required in each layer may be as low as 50 mV, and so ten layers can be stacked using only 0.5V. In a modest speed application (about 1M FFT/s) of a 1024-point FFT neural network, power consumption may be approximately 0.5 mW in various embodiments.

In various embodiments described herein, a ‘not fully connected’ CNN by reference to a CNN, can calculate the FFT of a set of input data. It will be appreciated that the FFT has commercial application but is not limited to this particular network.

FIG. 2 is a butterfly circuit in the prior art. The “butterflies” (as they are called by similarity to the shape of butterfly wings) accept two inputs and create two outputs. The butterflies are evidently in columns, and the columns all interconnect. Each butterfly has an associated parameter commonly called the ‘twiddle factor’, which is a specific root of minus one. The butterfly itself has two inputs and two outputs, as shown in more detail in FIG. 2

‘F’ is a complex multiplication factor, and the circles are adders. The bubble indicates negation. ‘F’ is the specific root of minus one, and all wires in FIG. 2 are complex quantities. Generally, ‘F’ varies both horizontally and vertically in the network. Mathematically, ‘F’ is a rotation in the complex plane. As a result, in FIG. 2, the complex quantity on the output of the ‘F’ triangle is a rotation of the input ‘B.’

In some embodiments, the challenge of an analog implementation of an FFT NN is that each butterfly must accurately compute its rotation, and the connectivity between the layers must not introduce significant delay or corrupt the complex quantity being routed between those layers. The second of these challenges is found to be the most difficult to achieve and, in some embodiments, is a motivation: currents are not attenuated as they travel over the wires to the next layer.

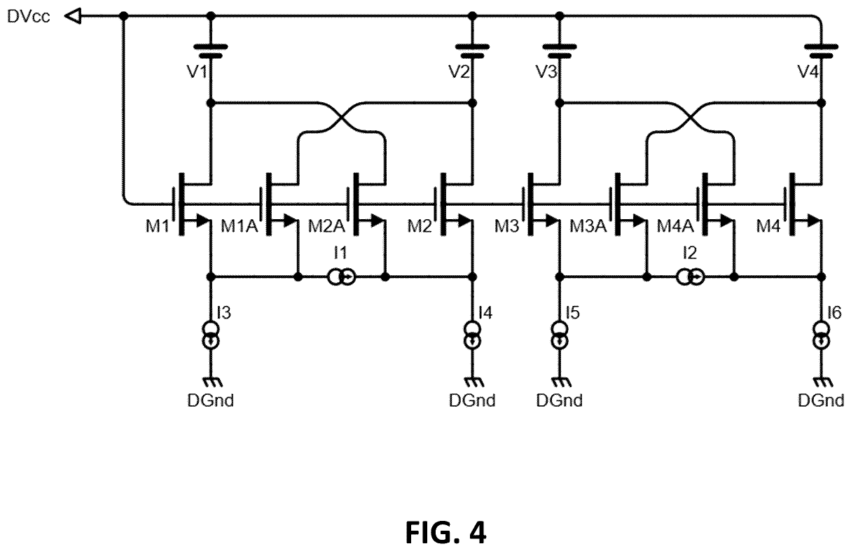

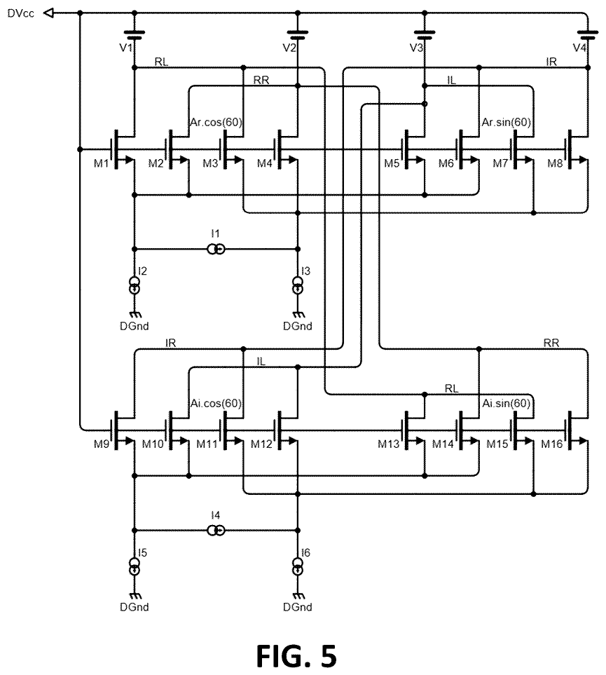

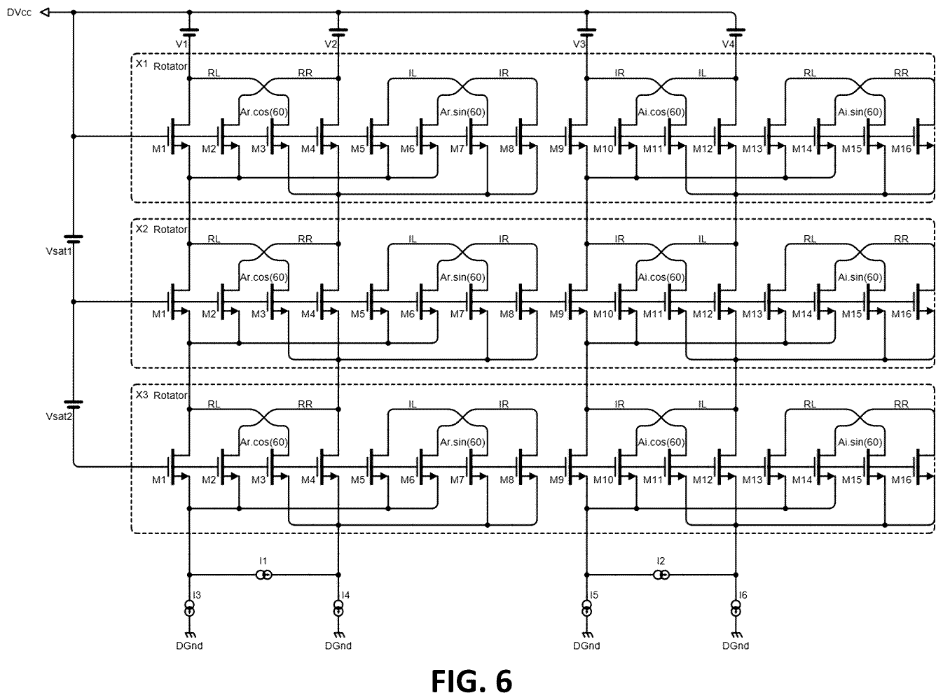

It will be appreciated that FIGS. 4, 5, and/or 6 may enable analog implementation of an FFT NN that reduces or eliminates current attenuation as current travels over the wires to the next layer. In some embodiments, the circuits in FIGS. 4, 5, and/or 6 accurately compute rotation and the connectivity in between layers does not have significant delay or corrupt the complex quantity being routed between the layers. It will be appreciated that these circuits, individually or together, may be utilized in IoT devices (e.g., Tiny ML, AI at the edge). For example, the circuit in FIG. 6 may be in or communicate with a small IoT device capable of listening and classifying sounds (e.g., a burglar alarm designed to receive audio and recognize the sound of breaking glass as opposed to a falling chair), make decisions, and provide signals or other functionality. As such, many of these devices include an analog-to-digital converter.

Reservoir computing is a computational framework that uses a dynamic system to process time-dependent or sequential data. It may be well-suited for tasks involving time series prediction, pattern recognition, and real-time signal processing. In some embodiments, the circuits of FIGS. 4, 5, and/or 6 may be utilized as an analog implementation of an FFT NN in reservoir computing.

It will be appreciated that, in many systems, the first few layers of a neural network (e.g., those that receive sensor data from one or more IoT devices) perform frequency decomposition. In some embodiments, these implementations (s) may be utilized for transfer learning and used as the first layer(s) of a neural network. For example, the circuit of FIG. 6 may be utilized to derive FFT as the first layers of a first neural network for speech recognition, and the same circuit design of FIG. 6 may be utilized to derive FFT as the first layers for image recognition. Further, the same circuit of FIG. 6 (as well as the circuits of FIGS. 4 and 5) have a significant savings of power.

In some embodiments, the circuits of FIGS. 4, 5, and/or 6 may be utilized as a part of an analog-to-digital converter. For example, the circuit of FIG. 6 can receive a signal and output a Fourier transform of the signal point by point.

The circuits of FIGS. 4, 5, and 6 may encode a signal as a current (e.g., current-mode signaling) and transmit it as a flow of charge per time rather than a potential (voltage) across the wire. Voltage-mode signaling in analog integrated circuits presents several challenges, particularly in nanoscale implementations. One of the primary issues is parasitic capacitance in the metal interconnects, which can absorb part of the intended charge during signal transmission. This causes a mismatch between the expected and actual charge received at the next computational stage, leading to inaccuracies in operations such as charge redistribution or summation. In switched-capacitor designs, for example, a given voltage is typically assumed to correspond to a specific amount of charge. However, due to charge sharing with unintended parasitic capacitance along the wire, the downstream node may receive significantly less than expected. Additionally, voltage signaling introduces latency, as the receiving node must undergo a capacitive charging process to reach the appropriate voltage level. Even with short interconnects, these delays can accumulate and significantly affect overall timing, sometimes resulting in delays on the order of nanoseconds.

In some embodiments of the circuits of FIGS. 4, 5, and 6, current-mode signaling offers several advantages over voltage-mode approaches, particularly in terms of signal fidelity and robustness to parasitic effects. By encoding information as a flow of current rather than a stored voltage, signal integrity can be preserved more reliably. A current signal, such as 10 nanoamperes flowing into a wire, is matched by an equal current being drawn at the other end due to the conservation of charge. This relationship holds regardless of interconnect parasitics, making the transmission more deterministic. Unlike voltage signals, current signals do not require a node to charge up to a new voltage level, thus bypassing the resistive-capacitive (RC) delay typically associated with voltage transitions. As a result, signal propagation is both faster and less susceptible to distortion or attenuation from intermediate capacitance, enabling more reliable communication across circuit components.

In the context of FFT implementations and neuromorphic hardware, current-mode signaling (e.g., in some embodiments of circuits in FIGS. 4, 5, and 6) proves especially beneficial. These architectures often require high interconnect density, with many stages of computation linked through complex metal routing. Using current-mode signaling in such environments ensures that signals maintain their magnitude and timing characteristics even across long or parasitically loaded interconnects. This is particularly important for analog FFT processors, where switched-capacitor methods rely on precise charge transfer; current-mode signaling helps mitigate the discrepancy between theoretical and actual charge delivery, thereby improving overall computational accuracy. Furthermore, as semiconductor nodes shrink to 22 nanometers and below, the relative impact of parasitic capacitance increases, making voltage-mode signaling increasingly error-prone. In contrast, current-mode techniques offer a more scalable and resilient solution, aligning well with the stringent demands of modern analog and mixed-signal processing systems.

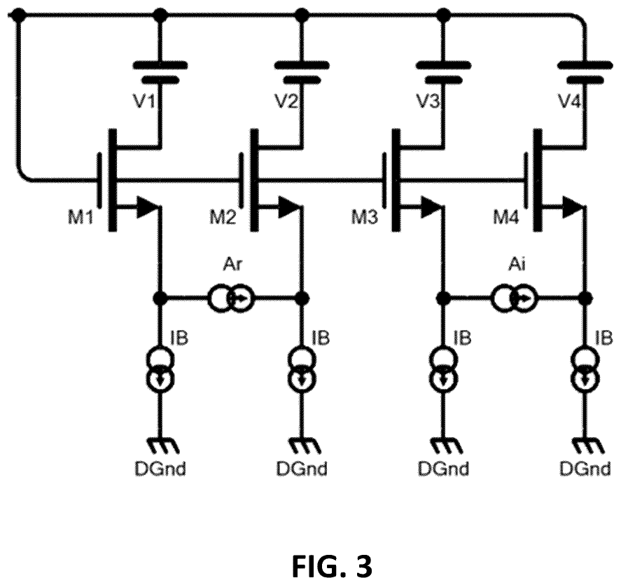

FIG. 3 depicts two sets of differential currents that encode real and imaginary parts of a complex number in some embodiments. M1, M2, M3, and M4 in this example are NMOS FETs. It will be appreciated that M1, M2, M3, and M4 may be PMOS FETs or other kinds of transistors (e.g., bipolar junction, FET), (or a combination of different kinds of transistors). V1, V2, V3, and V4 are voltage sources. It will be appreciated that V1-V4 are present for current measurement and are optional (e.g., the voltage sources may have 0 volts). For example, they may be replaced with a resistor and/or bare wire. The voltage sources shown in FIG. 3 aid in measuring and debugging. In some embodiments, production systems may not utilize voltage sources. As such, the example of FIG. 3 may be a convenience for building and debugging circuits.

IB elements represent current sources. Ar represents the real component and Ai represents the imaginary component.

As shown in FIG. 3, the difference of source currents between M1 and M2 represents the real part of the complex number. The difference of source currents between M3 and M4 represents the imaginary part of the complex number. In FIG. 3, the current sources Ar and Ai create the differential currents superimposed on the fixed currents from the IB sources. Ar and Ai swing positive and negative but never exceed IB, hence current is always flowing out of the sources of the NMOS.

NMOS is used as an example in FIG. 3. It will be appreciated that, in various embodiments, similar circuits using PMOS, BJT, or other three terminal devices are possible.

FIG. 4 depicts differential currents being split and multiplied by differing factors in some embodiments. FIG. 4 may assist to demonstrate how factors can be encoded in the relative area of devices. Those areas can also be achieved by repetition of the devices. For example, a relative area of two need not adjust the device length and width, but rather may, in some embodiments, place two similar devices in parallel. A plurality of devices in parallel may be a preferred way to make the relative areas.

M1 and M2 of FIG. 4 may be input transistors forming a differential pair. They receive current input signals driven at their gates. M1A and M2A are active loads that improve gain. Current from M1A may be combined with current from M1.

Returning to FIG. 4, if the area of M1 and M1A are equal, and the area of M2 and M2A are equal, the difference current I1 is multiplied by zero, since equal currents flow in the drains of the FETs. If the area of M1A and M2A are zero, meaning that no devices are present that have a cross-coupled output, then the difference current I1 appears in the drains of M1 and M2, meaning that I1 is multiplied by one. If the area of M1 is twice that of M1A and the area of M2 is twice that of M2A then the current splits such that ⅓rd of the I1 current appears as the output difference current. Thus, the relative areas of the ‘direct’ connected M1/M2 and the ‘cross-coupled’ M1A/M2A determine a multiplication factor applied to the difference current.

If ‘D’ is the area of the directed connected devices and ‘C’ is the area of the cross-coupled devices, then the multiplication factor is (D−C)/(D+C).

The relative area of the devices may be fixed at chip construction time or means well known in the art may be used to adjust the areas at run time.

There are differences in the circuit of FIG. 4 than a Gilbert multiplier. The Gilbert multiplier works by splitting currents between a long tailed pair, so a pair of devices that have a common tail on them, like M1 and M1A are a long tail pair, and they have a common tail hanging out of them down into i3. Gilbert multiplier struggles, and there have been many innovations to improve upon it, to match the common tail of two transistors, such that they create equal currents at the output. The circuit of FIG. 4, however, depicts “stealing” a fraction of the current from M1 and put it to the other side so when i3 flows, there is not an equal split of the current. To continue this example, if M1 comprises three devices, and M1A comprises one device, M2A comprises one device, and then M2 comprises three devices, then, if there's any current difference μl flowing between those two long tail pairs, that current difference will not flow between v1 and v2 and in fact, half of that current difference will flow in v1 and v2. As a result, the circuit of FIG. 4 may be part or include a multiplier (e.g., a multiplier of differential current signals by cross coupling certain numbers of devices in each side). In some embodiments, the device count of M1 is symmetrical (the same) to the device count of M2. Similarly, in some embodiments, the device count of M1A is symmetrical (the same) as the device count of M2A. The device count between M1 and M1A, in this example however, may be different (e.g., M1 and M2 each have an exact same number of devices, M1A and M2A each have an exact same number of devices, but the number of devices of M1 is not the same as the number of devices of M1A).

There may be any number of circuits that include the circuitry of FIG. 4. For example, there may be two sides, including one side that handles the real part of the complex number and the other side to handle the imaginary part. In this example, FIG. 4 depicts a left-hand-side (for handling a real part of the complex number). It will be appreciated that the discussion of FIG. 4 further applies the right-hand-side (for handling an imaginary part of the complex number).

Note that the difference current I1 for example, enters into four devices potentially of differing areas. However, the same difference current can enter multiple instances of the four devices as shown in FIG. 5 where for example, the difference current I1 enters the sources of M1 through M8. FIG. 5 is an example of complex number rotation in some embodiments.

If the total area of M1 through M4 equals the total area of M5 through M8 then that partition of the differencing current into the two groups of four devices is equal. Thus, half of I1 may be multiplied by the factor encoded in M1 through M4, and the other half multiplied by a possibly different factor encoded in M5 through M8.

A case of interest is when the group M1-M4 encode the cosine of an angle and the group M5-M8 encode the sine of the same angle. If that same cos/sin multiplication is repeated in M9 through M16 then I0 encoding the real quantity and I4 encoding the imaginary quantity, then the current difference as seen by the current difference through V1 and V2 can be interpreted as the real output, the current difference as seen by V3 and V4 can be interpreted as the imaginary output. The complex number so defined is the rotation of the complex input real part I0 imaginary part I4. Consequently, FIG. 5 can implement the twiddle factor ‘F’ in the butterfly of FIG. 2.

With regard to the example in FIG. 5, the areas may be different to enable Ai.cos(60) and Ai.sin(60). In some embodiments, the areas of M9 through M12 are such that the signal I4, which is the imaginary component of the signal, is multiplied by the cosine of 60, and that same signal i4 goes into another set of devices, M13 through M16, which results in it being multiplied by the sine of 60 degrees.

It will be appreciated that, as discussed herein, in some embodiments, the second transistor M2 and the third transistor M3 operate in parallel with M1 and M4 respectively and so split the current of the initial pair M1 and M4 into two parts. M2 directs a part of the M1 current into the drain of M4, and M3 directs part of the M4 current into the drain of M1. The current into the sources of the group of devices M1-M4 results in currents out of the drains of the group that are dependent on the relative sizes of the devices. The factor by which the output current difference in the drains, differs from input current difference at the sources, is adjustable by using different sizes, or equivalently different numbers of individual devices, in construction of M1-M4. It will be appreciated that this functional arrangement of transistors may be repeated throughout one or more circuits (e.g., See M5-M8, M9-M12, and M13-M16 of FIG. 5 as well as FIG. 6 showing similar repeated arrangements of transistors with the same internal functionality in the depicted embodiments).

FIG. 6 depicts stacking calculations without need for additional currents in some embodiments. In the example of FIG. 6, each of the elements named “Rotator” are the same circuit as in FIG. 5. The similarly named nodes (such as RL etc.) are making a connection by name to similar named nodes. For example, inside the topmost rotator X1 the drain of M1 named RL connects to the drain of M13 since it is also named RL.

In some embodiments, similar to the discussion regarding FIG. 5, each section in the dashed outline is the same; it is a rotation of the complex number expressed as a pair of difference currents. In this example, that rotation is 60°.

X3 the lower rotator, operates on the input defined by real part I1 and imaginary part 12. In FIG. 3, the output of X3 currents flow directly into the middle rotator M2 and similarly into the top rotator M1. The final outputs of X1 as measured by the current flowing in V1 through V4 is therefore, in this example, −1 times the input quantity. This is observed to be the case, three applications of a complex rotation of 60° is negation.

In some embodiments, all succeeding applications of the rotator, X2 sitting on top of X3 for example, are biased such that X3 devices have sufficient headroom to operate. In advanced processes such as 55 nm and 22 nm, that headroom may be different (e.g., the headroom may be as little as 50 mV or even less). This means that as many as ten processing steps can complete as a stacked set of operations in as little as 500 mV.

In various embodiments, considered as a neural network this has significant advantages. Each processing layer, the rotator in this case, is one more layer of the neural network connected by currents flowing from the prior network layer and consuming no additional current at all. The currents are connecting the layers, and current is not lost or corrupted by transmission (as a charge based analog neural network may be) and additionally those interlayer currents are powering the next layer.

In one example, in more detail, the first analog circuit may be the X1 upper rotator of FIG. 6, a second analog circuit may be the X2 middle rotator of FIG. 6, and a third analog circuit may be the X3 lower rotator of FIG. 6. It will be appreciated that the first, second, and third analog circuit may all be one circuit.

In this example, the X1 upper rotator may be configured to receive a current signal for frequency decomposition, the first analog circuit comprising a first transistor M1 including a first source configured to receive a first current, a first drain coupled to a third drain at a third transistor M3, and a signal input applied to a first gate, a voltage at the first gate determining how much current flows through the first transistor M1. The first analog circuit may include a second transistor M2 including a second source configured to receive the first current, a second drain coupled to a fourth drain at fourth transistor M4, and the signal input applied to a second gate, the voltage at the second gate determining how much current flows through the second transistor M2. The first analog circuit may include the third transistor M3 including a third source configured to receive a second current and the signal input applied to a third gate, the voltage at the third gate determining how much current flows through the third transistor M3. Further, the first analog circuit may include the fourth transistor M4 including a fourth source configured to receive the second current and the signal input applied to a first gate, the voltage at the first gate determining how much current flows through the fourth transistor M4.

It will be appreciated that the first analog circuit of claim 1, where the first transistor M1 and the fourth transistor M4 form a differential pair. In some embodiments, the second transistor M2 and the third transistor M3 are active loads that improve gain. The first, second, third, and fourth transistors may be any kind of FETs or other transistors (e.g., NMOS FETs in the example of FIG. 6).

The upper rotator X1 may further include a fifth transistor M5 including a fifth source configured to receive the first current, a fifth drain coupled to a seventh drain at a seventh transistor M7, and a signal input applied to a fifth gate, the voltage at the fifth gate determining how much current flows through the fifth transistor M5. The upper rotator may include a sixth transistor M6 including a sixth source configured to receive the first current, a sixth drain coupled to an eighth drain at fourth transistor M4, and the signal input applied to a sixth gate, the voltage at the sixth gate determining how much current flows through the sixth transistor M6. Further, the upper rotator X1 may include the seventh transistor M7 including a seventh source configured to receive the second current and the signal input applied to a seventh gate, the voltage at the seventh gate determining how much current flows through the seventh transistor M7. Moreover, the upper rotator X1 may include the eighth transistor M8 including an eighth source configured to receive the second current and the signal input applied to a eighth gate, the voltage at the eighth gate determining how much current flows through the eighth transistor M8.

In some embodiments, the first, second, third, and fourth transistors of the first analog circuit (e.g., upper rotator X1) apply to a real part of a complex number and the fifth, sixth, seventh, and eighth transistors apply to an imaginary part of the complex number. For example, the first current is the real part of the signal and the second current is the imaginary part of the signal. In various embodiments, a first area of the first, second, third, and fourth transistors of the first analog circuit are such that the first signal is multiplied by a cosine of 60 and a second area of the fifth, sixth, and seventh transistors are such that the first signal is multiplied by a sine of 60.

The first analog circuit may further comprise a ninth, tenth, eleventh, twelfth, thirteenth, fourteenth, fifteenth, and sixteenth transistor. The ninth transistor M9 may include a ninth source configured to receive a third current, a ninth drain coupled to an eleventh drain at an eleventh transistor M11, and the signal input applied to a ninth gate, the voltage at the ninth gate determining how much current flows through the ninth transistor M9. The tenth transistor M10 may include a tenth source configured to receive the third current, a tenth drain coupled to a twelfth drain at twelfth transistor M12, and the signal input applied to a tenth gate, the voltage at the tenth gate determining how much current flows through the tenth transistor M10. The eleventh transistor M11 may include an eleventh source configured to receive a fourth current and the signal input applied to an eleventh gate, the voltage at the eleventh gate determining how much current flows through the eleventh transistor M11. The twelfth transistor M12 may include a twelfth source configured to receive the fourth current and the signal input applied to a twelfth gate, the voltage at the twelfth gate determining how much current flows through the twelfth transistor M12. The thirteenth transistor M13 may include a thirteenth source configured to receive the third current, a thirteenth drain coupled to a fifteenth drain at a fifteenth transistor M15, and the signal input applied to a thirteenth gate, the voltage at the thirteenth gate determining how much current flows through the thirteenth transistor M13. The fourteenth transistor M14 may include a fourteenth source configured to receive the third current, a fourteenth drain coupled to a sixteenth drain at a sixteenth transistor M16, and the signal input applied to a fourteenth gate, the voltage at the fourteenth gate determining how much current flows through the fourteenth transistor M14. The fifteenth transistor M15 may include a fifteenth source configured to receive the fourth current and the signal input applied to a fifteenth gate, the voltage at the fifteenth gate determining how much current flows through the fifteenth transistor M15. The sixteenth transistor M16 may include a sixteenth source configured to receive the fourth current and the signal input applied to a sixteenth gate, the voltage at the sixteenth gate determining how much current flows through the sixteenth transistor M16.

A third area of the ninth, tenth, eleventh, and twelfth transistors M9, M10, M11, and M12 may be such that the third signal is multiplied by a cosine of 60 and a fourth area of the thirteenth, fourteenth, fifteenth, and sixteenth transistors M13, M14, M15, and M16 may be such such that the first signal is multiplied by a sine of 60.

The second analog circuit (X2 middle rotator) may include a first, second, third, fourth, fifth, sixth, seventh, eighth, ninth, tenth, eleventh, twelfth, thirteenth, fourteenth, fifteenth, and sixteenth transistor. The first transistor M1 may include a first source configured to receive a fifth current, a first drain coupled to a third drain at a third transistor M3, and a signal input applied to a first gate, a voltage at the first gate determining how much current flows through the first transistor M1. The second transistor M2 may include a second source configured to receive the fifth current, a second drain coupled to a fourth drain at fourth transistor M4, and the signal input applied to a second gate, the voltage at the second gate determining how much current flows through the second transistor M2. The third transistor M3 may include a third source configured to receive a sixth current and the signal input applied to a third gate, the voltage at the third gate determining how much current flows through the third transistor M3. The fourth transistor M4 may include a fourth source configured to receive the sixth current and the signal input applied to a first gate, the voltage at the first gate determining how much current flows through the fourth transistor M4. The fifth transistor M5 may include a fifth source configured to receive the fifth current, a fifth drain coupled to a seventh drain at a seventh transistor M7, and a signal input applied to a fifth gate, the voltage at the fifth gate determining how much current flows through the fifth transistor M5. The sixth transistor M6 may include a sixth source configured to receive the fifth current, a sixth drain coupled to an eighth drain at fourth transistor M4, and the signal input applied to a sixth gate, the voltage at the sixth gate determining how much current flows through the sixth transistor M6. The seventh transistor M7 may include a seventh source configured to receive the sixth current and the signal input applied to a seventh gate, the voltage at the seventh gate determining how much current flows through the seventh transistor M7. The eighth transistor M8 may include an eighth source configured to receive the sixth current and the signal input applied to an eighth gate, the voltage at the eighth gate determining how much current flows through the eighth transistor M8. The ninth transistor M9 may include a ninth source configured to receive a seventh current, a ninth drain coupled to an eleventh drain at an eleventh transistor M11, and the signal input applied to a ninth gate, the voltage at the ninth gate determining how much current flows through the ninth transistor M9. The tenth transistor M10 may include a tenth source configured to receive the seventh current, a tenth drain coupled to a twelfth drain at twelfth transistor M12, and the signal input applied to a tenth gate, the voltage at the tenth gate determining how much current flows through the tenth transistor M10. The eleventh transistor M11 may include an eleventh source configured to receive an eighth current and the signal input applied to an eleventh gate, the voltage at the eleventh gate determining how much current flows through the eleventh transistor M11. The twelfth transistor M12 may include a twelfth source configured to receive the eighth current and the signal input applied to a twelfth gate, the voltage at the twelfth gate determining how much current flows through the twelfth transistor M12. The thirteenth transistor M13 may include a thirteenth source configured to receive the seventh current, a thirteenth drain coupled to a fifteenth drain at a fifteenth transistor M15, and the signal input applied to a thirteenth gate, the voltage at the thirteenth gate determining how much current flows through the thirteenth transistor M13. The fourteenth transistor M14 may include a fourteenth source configured to receive the seventh current, a fourteenth drain coupled to a sixteenth drain at a sixteenth transistor M16, and the signal input applied to a fourteenth gate, the voltage at the fourteenth gate determining how much current flows through the fourteenth transistor M14. The fifteenth transistor M15 may include a fifteenth source configured to receive the eighth current and the signal input applied to a fifteenth gate, the voltage at the fifteenth gate determining how much current flows through the fifteenth transistor M15. The sixteenth transistor M16 may include a sixteenth source configured to receive the eighth current and the signal input applied to a sixteenth gate, the voltage at the sixteenth gate determining how much current flows through the sixteenth transistor M16. In some embodiments, the source of the first transistor of the first analog circuit is coupled to the drain of the first and third transistors of the second analog circuit, the source of the fourth transistor of the first analog circuit is coupled to the drain of the second and fourth transistors of the second analog circuit, the source of the ninth transistor of the first analog circuit is coupled to the drain of the ninth and eleventh transistors of the second analog circuit, and the source of the twelfth transistor of the first analog circuit is coupled to the drain of the tenth and twelfth transistors of the second analog circuit.

In some embodiments, a fifth area of the first, second, third, and fourth transistors of the second analog circuit are such that the first signal is multiplied by a cosine of 60, a sixth area of the fifth, sixth, seventh, and eighth transistors, are such that the first signal is multiplied by a sine of 60, a seventh area of the ninth, tenth, eleventh, and twelfth transistors of the second analog circuit are such that the first signal is multiplied by a cosine of 60, an eighth area of the thirteenth, fourteenth, fifteenth, and sixteenth transistors of the second analog circuit are such that the first signal is multiplied by a sine of 60.

The third analog circuit (X3 lower rotator) may include a first, second, third, fourth, fifth, sixth, seventh, eighth, ninth, tenth, eleventh, twelfth, thirteenth, fourteenth, fifteenth, and sixteenth transistor. The first transistor M1 may include a first source configured to receive a fifth current, a first drain coupled to a third drain at a third transistor M3, and a signal input applied to a first gate, a voltage at the first gate determining how much current flows through the first transistor M1. The second transistor M2 may include a second source configured to receive the fifth current, a second drain coupled to a fourth drain at fourth transistor M4, and the signal input applied to a second gate, the voltage at the second gate determining how much current flows through the second transistor M2. The third transistor M3 may include a third source configured to receive a sixth current and the signal input applied to a third gate, the voltage at the third gate determining how much current flows through the third transistor M3. The fourth transistor M4 may include a fourth source configured to receive the sixth current and the signal input applied to a first gate, the voltage at the first gate determining how much current flows through the fourth transistor M4. The fifth transistor M5 may include a fifth source configured to receive the fifth current, a fifth drain coupled to a seventh drain at a seventh transistor M7, and a signal input applied to a fifth gate, the voltage at the fifth gate determining how much current flows through the fifth transistor M5. The sixth transistor M6 may include a sixth source configured to receive the fifth current, a sixth drain coupled to an eighth drain at fourth transistor M4, and the signal input applied to a sixth gate, the voltage at the sixth gate determining how much current flows through the sixth transistor M6. The seventh transistor M7 may include a seventh source configured to receive the sixth current and the signal input applied to a seventh gate, the voltage at the seventh gate determining how much current flows through the seventh transistor M7. The eighth transistor M8 may include an eighth source configured to receive the sixth current and the signal input applied to an eighth gate, the voltage at the eighth gate determining how much current flows through the eighth transistor M8. The ninth transistor M9 may include a ninth source configured to receive a seventh current, a ninth drain coupled to an eleventh drain at an eleventh transistor M11, and the signal input applied to a ninth gate, the voltage at the ninth gate determining how much current flows through the ninth transistor M9. The tenth transistor M10 may include a tenth source configured to receive the seventh current, a tenth drain coupled to a twelfth drain at twelfth transistor M12, and the signal input applied to a tenth gate, the voltage at the tenth gate determining how much current flows through the tenth transistor M10. The eleventh transistor M11 may include an eleventh source configured to receive an eighth current and the signal input applied to an eleventh gate, the voltage at the eleventh gate determining how much current flows through the eleventh transistor M11. The twelfth transistor M12 may include a twelfth source configured to receive the eighth current and the signal input applied to a twelfth gate, the voltage at the twelfth gate determining how much current flows through the twelfth transistor M12. The thirteenth transistor M13 may include a thirteenth source configured to receive the seventh current, a thirteenth drain coupled to a fifteenth drain at a fifteenth transistor M15, and the signal input applied to a thirteenth gate, the voltage at the thirteenth gate determining how much current flows through the thirteenth transistor M13. The fourteenth transistor M14 may include a fourteenth source configured to receive the seventh current, a fourteenth drain coupled to a sixteenth drain at a sixteenth transistor M16, and the signal input applied to a fourteenth gate, the voltage at the fourteenth gate determining how much current flows through the fourteenth transistor M14. The fifteenth transistor M15 may include a fifteenth source configured to receive the eighth current and the signal input applied to a fifteenth gate, the voltage at the fifteenth gate determining how much current flows through the fifteenth transistor M15. The sixteenth transistor M16 may include a sixteenth source configured to receive the eighth current and the signal input applied to a sixteenth gate, the voltage at the sixteenth gate determining how much current flows through the sixteenth transistor M16. In some embodiments, the source of the first transistor of the second analog circuit is coupled to the drain of the first and third transistors of the third analog circuit, the source of the fourth transistor of the second analog circuit is coupled to the drain of the second and fourth transistors of the third analog circuit, the source of the ninth transistor of the second analog circuit is coupled to the drain of the ninth and eleventh transistors of the third analog circuit, and the source of the twelfth transistor of the second analog circuit is coupled to the drain of the tenth and twelfth transistors of the third analog circuit.

In some embodiments, a fifth area of the first, second, third, and fourth transistors of the third analog circuit are such that the first signal is multiplied by a cosine of 60, a sixth area of the fifth, sixth, seventh, and eighth transistors of the third analog circuit are such that the first signal is multiplied by a sine of 60, a seventh area of the ninth, tenth, eleventh, and twelfth transistors of the third analog circuit are such that the first signal is multiplied by a cosine of 60, an eighth area of the thirteenth, fourteenth, fifteenth, and sixteenth transistors of the third analog circuit are such that the first signal is multiplied by a sine of 60.

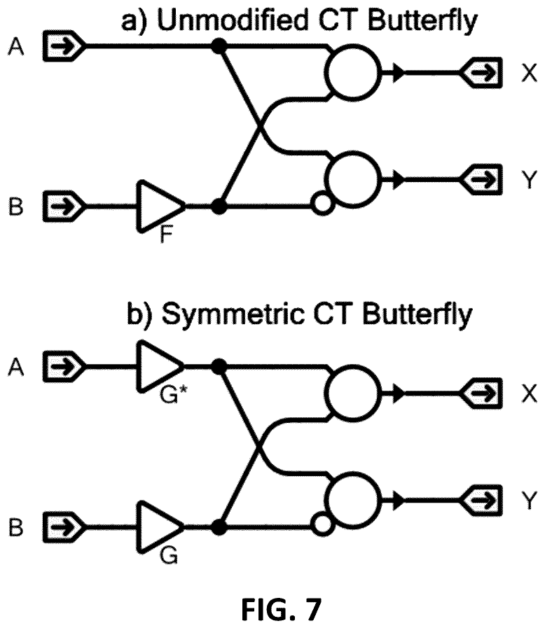

FIG. 7 is an example of an alternative butterfly circuit in some embodiments. The alternative butterfly configuration is possible in the FFT calculation. This alternate configuration leads to additional overhead in a digital implementation (since it includes a second complex rotator) but has an advantage in the analog implementation with no additional overhead. The alternate butterfly is seen to be the sum (X) and the difference (Y) of the output of two complex rotators. (Additionally, one rotator is the complex conjugate of the other hence the relative area programming is the same with a swap of the outputs).

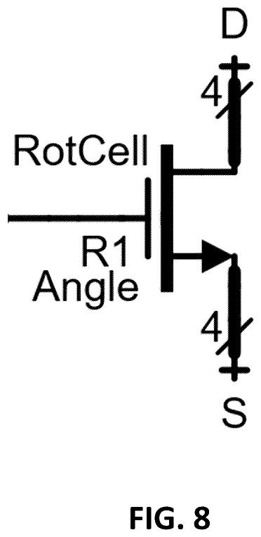

FIG. 8 depicts a rotator represented as a FET-like symbol with multiple drains and sources in some embodiments. in some embodiments, FIG. 8 includes a depiction of a rotator (FIG. 5 may be depict the rotator as are each of the elements X1 through X3 in FIG. 6) as a single device with multiple drains and sources and having a parameter to determine the relative areas.

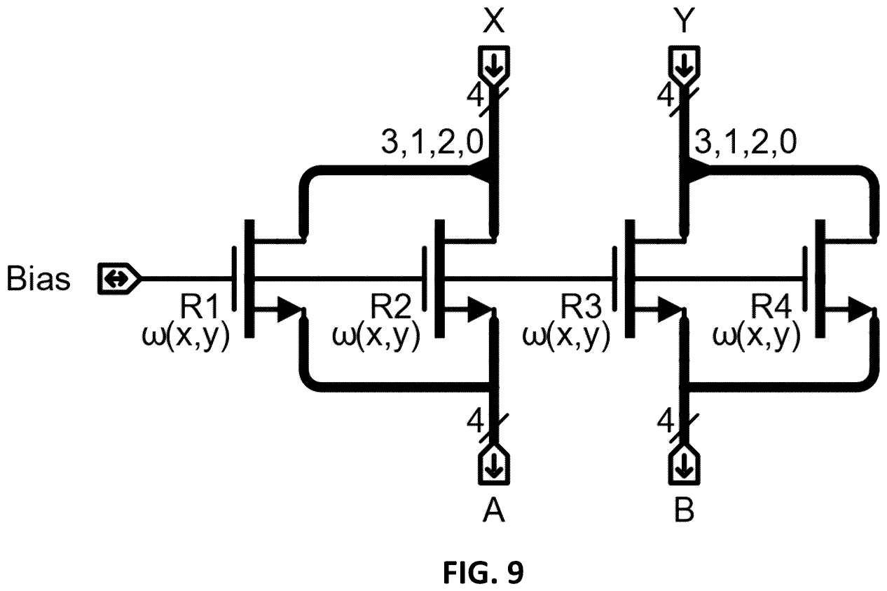

With this rotator symbol, a butterfly circuit may be constructed as shown in FIG. 9. FIG. 9 depicts four rotator circuits configured to make a current mode butterfly in some embodiments. In this example, each rotator may be assigned an angle that depends upon its x-y coordinate in the NN.

For a typical FFT of 1024-points, 256 instances of the circuit of FIG. 9 may be needed in each of 10 layers. 256 instances because each butterfly has two complex inputs. In a real-value application, it will be appreciated how to use the real and complex part of the analytic input signal as separate non-analytic real values. Hence each butterfly provides four real value inputs, hence for 1024-points 256 butterflies may be needed.

The ten layers needed for 1024-points may be stacked as shown in the rotator example of FIG. 6.

In some embodiments, each of the butterflies requires as little as 2 μA to operate. Hence across the 256 instances of the layer 510 μA is consumed, because the layers may be stacked this is the total current consumption. A power supply of 1 v is more than sufficient, hence the total power dissipation in a 1024-point FFT is 510 μW. Using the innovations described in U.S. Pat. No. 12,038,999 (round robin) at that power level on a 55 nm or lower process the FFT computes at a rate of 1 Million FFT's per second.

Any property of an electronic system (e.g., voltage, charge, time, and current), is a candidate for a signal representation. For example, an audio system may use the difference of two voltages to represent the sound pressure level and thereby amplify and reproduce sound.

In various embodiments, a local connection (e.g., on a printed circuit board or chip) may be utilized. For example, the circuits of FIG. 4, 5, or 6 may be utilized in conjunction with one or more of these embodiments.

Various embodiments described herein offer a greatly simplified means to communicate considerable amounts of data on a single bit connection. A high order single bit sigma delta (ΣΔ) modulator may reduce the noise as the frequency is reduced relative to the Over Sampling Ratio (OSR). The modulator in these examples is a single-bit sixth-order digital modulator.

It will be appreciated that orthogonal frequency division multiplexing (OFDM) may be used to encode data across multiple orthogonal subcarriers (frequencies). Each subcarrier may transmit part of the data stream, which may help with bandwidth efficiency and resilience to multipath interference.

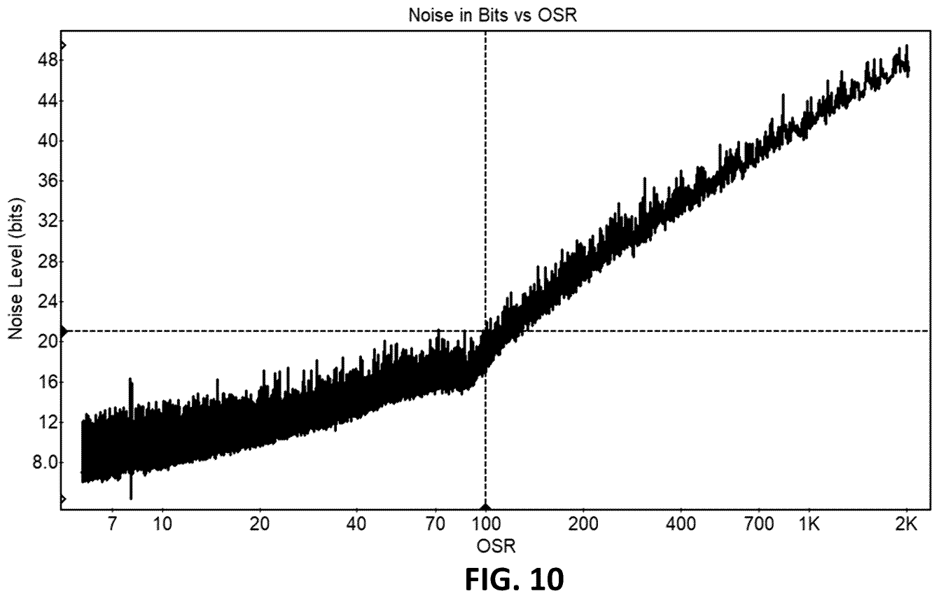

FIG. 10 depicts noise of a single bit high order ΣΔ vs OSR. In particular, FIG. 10 depicts that if a frequency is applied at 1/100th of the clock rate (that is at an OSR of 100) then that signal will experience a noise level of about 21 bits. A single OFDM carrier at 100 OSR could then comfortably encode a complex number of, for example, 18 bit noise in the real and imaginary components. This means that in every 100 cycles of the ΣΔ modulator, 36 bits have been communicated.

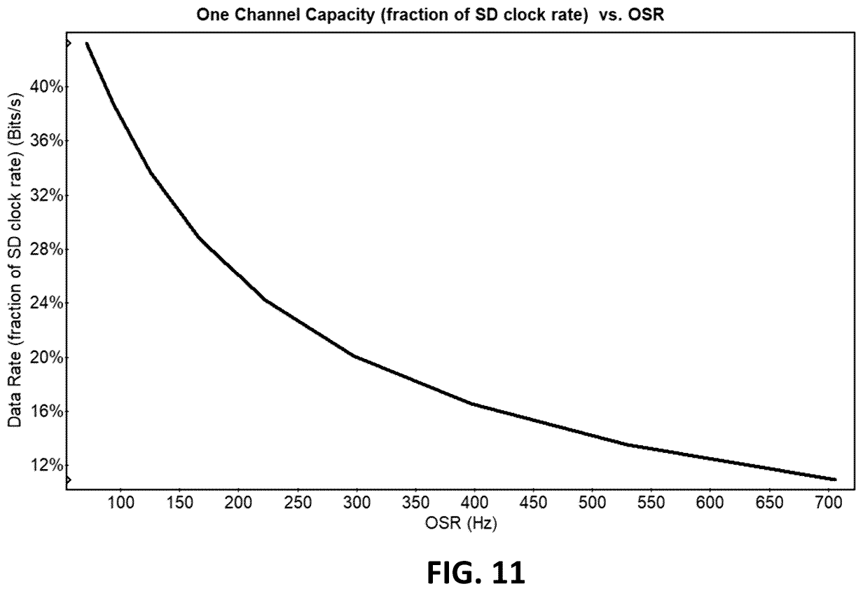

FIG. 11 depicts channel capacity as a fraction of the ΣΔ clock vs. OSR of the single OFDM tone in some embodiments. In this example, FIG. 11 depicts the calculated channel capacity vs the OSR. This demonstrates that as the OSR is increased, while the number of bits of accuracy greatly increases (as on the y-axis of FIG. 11), the number of cycles (the OSR) increases and outweighs the choice of a lower OSR.

All ΣΔ modulators exhibit an increased noise as the OSR decreases; this is due to the need to stabilize the ΣΔ loop. The preferred (e.g., optimum) OSR to insert a tone is the point where the slope of the noise begins to fall. This is about 100 OSR as seen in FIG. 10. FIG. 11 shows that a single tone at the optimum frequency can encode data at a rate of about 40% of the ΣΔ clock rate.

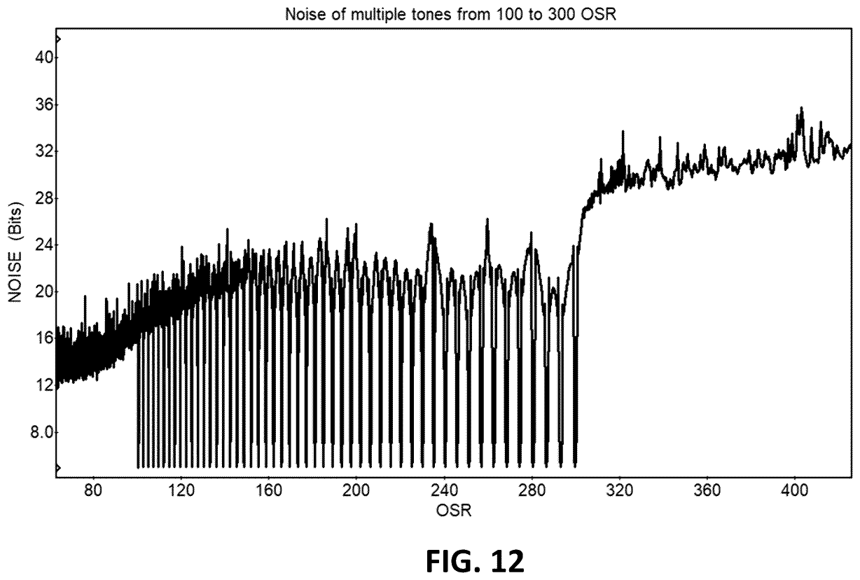

In various embodiments, the concept of OFDM allows multiple carriers, each modulated by a given phase and amplitude. FIG. 12 depicts multiple ODFM carriers in the ΣΔ output in some embodiments. In this example, FIG. 12 shows the noise of 51 separate frequency carriers from 100 to 300 OSR.

In some embodiments, the peak amplitude of each carrier is reduced so that the sum does not overload the ΣΔ modulator. In this example, the peak is set to −30 db—a loss of 6 bits in each carrier. Additionally, the noise level is comfortably above 16 bits for higher OSR, but note the 100 OSR has reduced to about 15 bits. Applying that worst-case noise to each carrier, the system is encoding 18 bits (9 bits in each of the real and imaginary parts) in the ODFM carrier. The total number of bits is then 51*18 or 918 bits at the rate of the largest OSR which is 300 in this example. Hence, in every 300 cycles, 918 bit have been communicated or 3.6 times the rate of the ΣΔ clock.

It will be appreciated that the ΣΔ need not be low pass as used in these examples. The same principle may apply to a set of OFDM carriers placed in the low noise band-pass section of a modulator.

Different clock cycles may be utilized. For example, other clock cycles (e.g., other than 300 clock cycles) may be used (e.g., for those carriers that are at, for example, 100 OSR). If treated separately, they may deliver data 3× faster.

Further, it will be appreciated that the assumption that the noise is that of the lowest OSR carrier, 100 in this example, is conservative. For example, higher OSR carriers have less noise.

Applying these principles and removing the conservative assumptions may significantly increase the data rate to perhaps 8 times the rate of the ΣΔ clock. Finally, there is no reason to stop at 51 carriers. As many as 128 or 256 may be used, increasing further the rate of data transfer to perhaps 40 times the rate of the ΣΔ clock.

When a stream of ΣΔ data has been created on which are imposed a set of tones carrying a differing phase and amplitude, using the OFDM principle, that stream of single bit data may be sent to a receiving device.

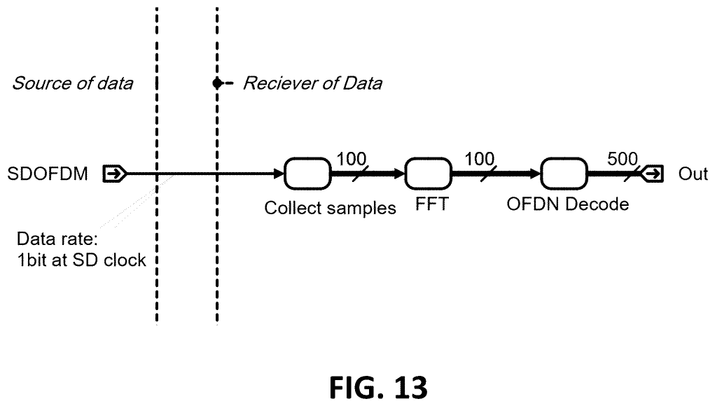

FIG. 13 depicts the decoding of the stream of ΣΔ data having OFDM encoding by a receiving device in some embodiments. The transmitter of the OFDM data has encoded the data at such that an FFT over an interval in the ΣΔ stream will result in tones each of which is one of the OFDM data items. The decoding of an OFDM stream uses a constellation of points in the real and imaginary components of that tone to find the data.

While the method of FIG. 13 works well and needs only a single bit to be transmitted between the source and the receiver, that single bit may be at a high clock rate. For example, the highest frequency OFDM tone may be at the ΣΔ clock rate divided by 100. It will be appreciated that there may be many more OFDM tones below the highest, but they do not enter into this calculation in this example. Thus, in this example, the clock is 100× faster than the highest tone frequency.

An example would be delivering data from a multichannel biomedical device such as an electroencephalogram (EEG). An EEG may use as many as 64 sensors. In this example, the EEG uses 32 OFDM tones, the real part and the imaginary part encoding two channels.

The bandwidth of each EEG channel in this example is 1 KHz, thus each of the 32 OFDM tones are separated by at least 1 KHz (e.g., 2 KHz). The lowest tone in this example must be at least 1 KHz above DC (e.g., again let us assume 2 Khz), thus the 32^{nd} tone is at 64 KHz. Each of the 64 data stream from the EEG carries 16 bits of data in this example. Thus, the signal to noise ratio of all the OFDM carriers on the ΣΔ stream must be at least 96 db, let us assume 105 dB. Therefore, the OSR at the highest tone of 64 KHz needs to be at least 100 if a high order modular—say 4th order or higher—is used. These considerations result in a clock rate to the ΣΔ of 100×64 Khz of 6.4 MHZ.

In comparison with a simple PDM stream of 64 words of 16 bits at 1 KHz, the data rate in that example requires 64*16*1 k=1 Mhz. Consequently, while the ΣΔ OFDM implementation performs, it has resulted in a higher rate of data transfer than simple PCM encoding: 6.4 MHz to 1 MHz or 6.4 times more data per second in this example. In some embodiments, it will be appreciated that the ΣΔ OFDM implementation may produce a reduced data rate that is less than a Pulse Code Modulation (PCM) serial clock.

Because the OSR needed was 100:1, all the frequency content above ΣΔ clk/100 is not used. As a result, some embodiments may filter it out before transmission to the receiver.

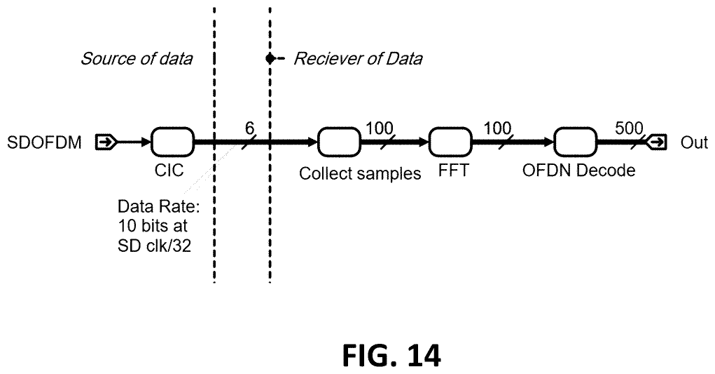

FIG. 14 depicts an example of the implementation of a filter (e.g., a 6-bit Cascaded Integrator-Comb (CIC)) prior to transmission in some embodiments. In one example, the encoder places the highest OFDM tone at 1/100th of the SD clock. As a result, there is no need to send high frequency data across the transmission medium—it contains no information (although it could if the high frequency data contains framing data, for example, but this does not impact the OFDM methods described).

In various embodiments, a processor (e.g., of digital device, motherboard, ASIC, or the like) is configured to encode OFDM symbols into a first sigma-delta (ΣΔ) modulated bitstream, such that spectral content of the first sigma-delta (ΣΔ) modulated bitstream contains tones at subcarrier frequencies corresponding to the encoded symbols. The transmitter may be configured to apply a filter to the first sigma-delta (ΣΔ) modulated bitstream to remove frequency content above a sigma delta clock rate (e.g., above the highest frequency OFDM tone) to create a filtered sigma-delta (ΣΔ) modulated bitstream and transmit the filtered sigma-delta (ΣΔ) modulated bitstream at a reduced data rate to a receiver. For example, the transmitter may be configured to apply a filter to the first sigma-delta (ΣΔ) modulated bitstream to remove frequency content above a fraction of the sigma delta clock rate. In some embodiments, the processor may utilize any of the circuits discussed with regard to FIGS. 4, 5, and 6 to encode data for transmission.

In this example, the 6-bit CIC filter outputs 6 bits at a rate of 1/64th of the clock. The receiving section is the same: it collects a sequence of the filtered data, performs FFT and recovers the data as before.

For the purpose of this example, the rate of data crossing the boundary is not 6.4 MHZ but 6.4 Mhz*6/64 or 600 KHz. The ΣΔ OFDM stream encoding reduces the data rate transferred from the source to the receiver.

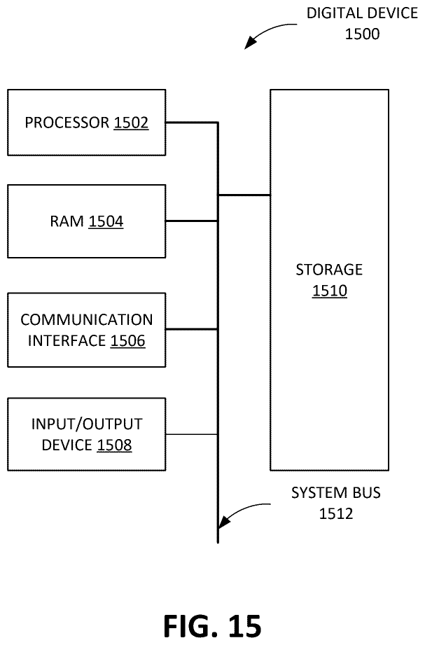

FIG. 15 depicts a block diagram of an example digital device 1500 according to some embodiments. The digital device 1500 is shown in the form of a general-purpose computing device. The digital device 1500 includes at least one processor 1502, RAM 1504, communication interface 1506, input/output device 1508, storage 1510, and a system bus 1512 that couples various system components including storage 1510 to the at least one processor 1502. A system, such as a computing system, may be or include one or more of the digital devices 1500.

System bus 1512 represents one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus.

The digital device 1500 typically includes a variety of computer system readable media, such as computer system readable storage media. Such media may be any available media that is accessible by any of the systems described herein and it includes both volatile and nonvolatile media, removable and non-removable media.

In some embodiments, the at least one processor 1502 is configured to execute executable instructions (for example, programs). In some embodiments, at least one processor 1502 comprises circuitry or any processor capable of processing the executable instructions.

In some embodiments, RAM 1504 stores programs and/or data. In various embodiments, working data is stored within RAM 1504. The data within RAM 1504 may be cleared or ultimately transferred to storage 1510, such as prior to resetting and/or powering down the digital device 1500.

In some embodiments, the digital device 1500 is coupled to a network via communication interface 1506. The network may be, for example, any network including, but not limited to a local area network (LAN), a general wide area network (WAN), and/or a public network (for example, the Internet).

In some embodiments, input/output device 1508 is any device that inputs data (for example, mouse, keyboard, stylus, sensors, etc.) or outputs data (for example, speaker, display, virtual reality headset).

In some embodiments, storage 1510 can include computer system readable media in the form of non-volatile memory, such as read only memory (ROM), programmable read only memory (PROM), solid-state drives (SSD), flash memory, and/or cache memory. Storage 1510 may further include other removable/non-removable, volatile/non-volatile computer system storage media. By way of example only, storage 1510 can be provided for reading from and writing to a non-removable, non-volatile magnetic media. The storage 1510 may include a non-transitory computer-readable medium, or multiple non-transitory computer-readable media, which stores programs or applications for performing functions such as those described herein. Although not shown, a magnetic disk drive for reading from and writing to a removable, non-volatile magnetic disk (for example, a “floppy disk”), and an optical disk drive for reading from or writing to a removable, non-volatile optical disk such as a CDROM, DVD-ROM or other optical media can be provided. In such instances, each can be connected to the system bus 1512 by one or more data media interfaces. As will be further depicted and described below, storage 1510 may include at least one program product having a set (for example, at least one) of program modules that are configured to carry out the functions of embodiments of the invention. In some embodiments, RAM 1504 is found within storage 1510.

Programs/utilities, having a set (at least one) of program modules, such as those for encoding or decoding data, may be stored in storage 1510 by way of example, and not limitation, as well as an operating system, one or more application programs, other program modules, and program data. Each of the operating systems, one or more application programs, other program modules, and program data or some combination thereof may include an implementation of a networking environment. Program modules generally carry out the functions and/or methodologies of embodiments of the invention as described herein.

It should be understood that although not shown, other hardware and/or software components could be used in conjunction with the digital device 1500. Examples include, but are not limited to microcode, device drivers, redundant processing units, and external disk drive arrays, RAID systems, tape drives, and data archival storage systems, etc.

Exemplary embodiments are described herein in detail with reference to the accompanying drawings. However, the present disclosure can be implemented in various manners, and thus should not be construed to be limited to the embodiments disclosed herein. On the contrary, those embodiments are provided for the thorough and complete understanding of the present disclosure, and completely conveying the scope of the present disclosure.

It may be appreciated that aspects of one or more embodiments may be embodied as a system, method, or computer program product. Accordingly, aspects (e.g., modules discussed herein) may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), a solid state drive (SSD), an optical fiber, a portable compact disc read-only memory (CD-ROM), an optical storage device, a magnetic storage device, or any suitable combination of the foregoing. In the context of this document, a computer readable storage medium may be any tangible medium that can contain or store a program or data for use by or in connection with an instruction execution system, apparatus, or device.

A transitory computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present invention may be written in any combination of one or more programming languages, including an object-oriented programming language such as Java, Smalltalk, C++, Python, or the like and conventional procedural programming languages, such as the “C” programming language or similar programming languages. The computer program code may execute entirely on any of the systems described herein or on any combination of the systems described herein.

Aspects of the present invention are described below with reference to flowchart illustrations and/or block diagrams of methods, apparatus (systems) and computer program products according to embodiments of the invention. It may be understood that each block of the flowchart illustrations and/or block diagrams, and combinations of blocks in the flowchart illustrations and/or block diagrams, can be implemented by computer program instructions. These computer program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The disclosed system has been explained above with reference to several embodiments. Other embodiments will be apparent to those skilled in the art in light of this disclosure. Certain aspects of the described method and apparatus may readily be implemented using configurations other than those described in the embodiments above, or in conjunction with elements other than or in addition to those described above.

For example, as is well understood by those of skill in the art, various choices will be apparent to those of skill in the art. Further, the illustration of transistors and the associated feedback loops, resistors, etc., is exemplary; one of skill in the art will be able to select the appropriate number of transistors and related elements that is appropriate for a particular application.

These and other variations upon the embodiments are intended to be covered by the present disclosure, which is limited only by the appended claims.

The disclosed system has been explained above with reference to several embodiments. Other embodiments will be apparent to those skilled in the art in light of this disclosure. Certain aspects of the described method and apparatus may readily be implemented using configurations other than those described in the embodiments above, or in conjunction with elements other than or in addition to those described above.

For example, as is well understood by those of skill in the art, various choices will be apparent to those of skill in the art. Further, the illustration of transistors and the associated feedback loops, resistors, etc., is exemplary; one of skill in the art will be able to select the appropriate number of transistors and related elements that is appropriate for a particular application.

These and other variations upon the embodiments are intended to be covered by the present disclosure, which is limited only by the appended claims.

1. A system for encoding OFDM data, the system comprising:
a processor configured to encode OFDM symbols into a first sigma-delta (ΣΔ) modulated bitstream, such that spectral content of the first sigma-delta (ΣΔ) modulated bitstream contains tones at subcarrier frequencies corresponding to the encoded symbols; and
a transmitter configured to transmit the sigma-delta (ΣΔ) modulated bitstream to a receiver.

2. The system of claim 1, the transmitter further configured to apply a filter to the first sigma-delta (ΣΔ) modulated bitstream to remove frequency content above a fraction of a sigma delta clock rate to create a filtered sigma-delta (ΣΔ) modulated bitstream and transmit the filtered sigma-delta (ΣΔ) modulated bitstream at a reduced rate to a receiver.

3. The system of claim 1, wherein the sigma-delta (ΣΔ) modulated bitstream is a one-bit sigma-delta (ΣΔ) modulated bitstream.

4. The system of claim 1, wherein the receiver that receives the sigma-delta (ΣΔ) modulated bitstream from the transmitter, accumulates samples of the sigma-delta (ΣΔ) modulated bitstream, applies an FFT to recover the OFDM symbols, and decodes the OFDM symbols.

5. The system of claim 2, wherein the filter is a cascaded integrator-comb (CIC) filter.

6. The system of claim 5, wherein the CIC filter is a 6-bit CIC filter configured to output a predetermined number of bits and transmit the sigma-delta (ΣΔ) modulated bitstream to the receiver, the reduced data rate being at a rate of 1/64^{th} of a clock.

7. The system of claim 1, wherein data to be encoded into the OFDM symbols is received from a multichannel device generating complex signals to be encoded on more than one channel.

8. The system of claim 5, wherein the reduced data rate is less than a Pulse Code Modulation (PCM) serial clock.

9. The system of claim 1, wherein the processor inserts a tone at a point where noise begins to fall at a percentage of clock rate with respect to increasing an over sampling ratio (OSR).

10. The system of claim 9, wherein the processor inserts the tone at approximately 40% of a sigma-delta (ΣΔ) clock rate.

11. The system of claim 9, wherein there are a plurality of carriers and the tones are at points such that a data rate of a data transfer is a multiple of the sigma-delta (ΣΔ) clock rate.

12. The system of claim 1, wherein the system comprises a first analog circuit configured to assist in encoding data, the first analog circuit comprising:
a first transistor M1 including a first source configured to receive a first current, a first drain coupled to a third drain at a third transistor M3, and a signal input applied to a first gate, a voltage at the first gate determining how much current flows through the first transistor M1;
a second transistor M2 including a second source configured to receive the first current, a second drain coupled to a fourth drain at fourth transistor M4, and the signal input applied to a second gate, the voltage at the second gate determining how much current flows through the second transistor M2;
the third transistor M3 including a third source configured to receive a second current and the signal input applied to a third gate, the voltage at the third gate determining how much current flows through the third transistor M3; and
the fourth transistor M4 including a fourth source configured to receive the second current and the signal input applied to a first gate, the voltage at the first gate determining how much current flows through the fourth transistor M4.

13. The system of claim 12, where the first transistor M1 and the fourth transistor M4 form a differential pair.

14. The system of claim 13, wherein the second transistor M2 and the third transistor M3 are active loads that improve gain.

15. The system of claim 12, wherein the first, second, third, and fourth transistors are NMOS FETs.

16. The system of claim 12, further comprising:
a fifth transistor M5 including a fifth source configured to receive the first current, a fifth drain coupled to a seventh drain at a seventh transistor M7, and a signal input applied to a fifth gate, the voltage at the fifth gate determining how much current flows through the fifth transistor M5;
a sixth transistor M6 including a sixth source configured to receive the first current, a sixth drain coupled to an eighth drain at eighth transistor M8, and the signal input applied to a sixth gate, the voltage at the sixth gate determining how much current flows through the sixth transistor M6;
the seventh transistor M7 including a seventh source configured to receive the second current and the signal input applied to a seventh gate, the voltage at the seventh gate determining how much current flows through the seventh transistor M7; and
the eighth transistor M8 including an eighth source configured to receive the second current and the signal input applied to an eighth gate, the voltage at the eighth gate determining how much current flows through the eighth transistor M8.

17. The system of claim 16, wherein the first, second, third, and fourth transistors apply to a real part of a complex number and the fifth, sixth, seventh, and eighth transistors apply to an imaginary part of the complex number.

18. The system of claim 17, where the first current is the real part of the signal and the second current is the imaginary part of the signal.

19. The system of claim 18, wherein a first area of the first, second, third, and fourth transistors of the first analog circuit are such that the first signal is multiplied by a cosine of 60 and a second area of the fifth, sixth, seventh, and eighth transistors of the first analog circuit are such that the first signal is multiplied by a sine of 60.

20. A method, comprising:
encoding OFDM symbols, by a processor, into a first sigma-delta (ΣΔ) modulated bitstream, such that spectral content of the first sigma-delta (ΣΔ) modulated bitstream contains tones at subcarrier frequencies corresponding to the encoded symbols; and
transmitting, by a transmitter, the sigma-delta (ΣΔ) modulated bitstream to a receiver.
